(19) United States
(12) Patent Application Publication
(10) Pub. No.: US 2025/0323171 A1
(43) Pub. Date: Oct. 16, 2025

(54) SIDE WETTABLE SEMICONDUCTOR PACKAGE WITH PROBE MARKS

(71) Applicant: PANJIT INTERNATIONAL INC., Kaohsiung City (TW)

(72) Inventors: CHUNG-HSIUNG HO, Kaohsiung City (TW); PING-JUI HSIEH, Kaohsiung City (TW)

(21) Appl. No.: 18/766,107

(22) Filed: Jul. 8, 2024

(30) Foreign Application Priority Data
Apr. 12, 2024 (TW) 113113798

(51) Int. Cl. H01L 23/544; H01L 21/66; H01L 23/498

(52) U.S. Cl. CPC H01L 23/544; H01L 23/49838; H01L 22/32; H01L 2223/54433

(57) ABSTRACT

A side wettable semiconductor package with probe mark has a body and multiple conductive pads. The conductive pads are arranged at intervals along edges of the body. Each conductive pad has a first surface exposed from a bottom of the body and has a second surface exposed from a side surface of the body. In an electrical test process for the conductive pads, each conductive pad is pressed by a respective probe to form a probe mark that extends to the side surface of the body. The probe mark allows solder to be easily adhered to, thereby facilitating the inspection of the solder joint on each conductive pad. The side wettable semiconductor package may be fabricated in a simple way without using a lead frame specially designed or additional processes.

### CROSS REFERENCE TO RELATED APPLICATIONS

This non-provisional application claims the benefit under 35 U.S.C. § 119 (a) to patent application No. 113113798 filed in Taiwan on Apr. 12, 2024, which is hereby expressly incorporated by reference into the present application.

### BACKGROUND OF THE INVENTION

### 1. Field of the Invention

The present invention relates to a side wettable semiconductor package, particularly to a semiconductor package with probe marks for side wettable purpose.

### 2. Description of the Related Art

For specific types of packages, such as quad flat no-lead (QFN) or dual flat no-lead (DFN) packages, a plurality of conductive pads is fabricated on a bottom of such a package and designed to be connected to a circuit board by soldering. Determining whether the conductive pads are well connected to the circuit board is not easy by merely inspecting the bottom of the package. Therefore, each conductive pad of the QFN or DFN package may be formed to be partially exposed from a side surface of the package where solder can wet and adhere to, which allowing an optical inspection system checks whether the package is soldered to the circuit board in a reliable way. Such a package having conductive pads exposed form its side surface for purpose of checking solder connection is called as side wettable package.

The side wettable package can be manufactured based on a lead frame with special structure. After sawing the lead frame by the singulation process, the special structure of the lead frame may constitute side wettable conductive pads.

Another manner to fabricate the side wettable package may use a common lead frame rather than the type of special structure mentioned above. The common lead frame will be processed by a series of particularly programmed manufacturing processes such as cutting, etching etc. to form wettable conductive pads. However, any of the above-mentioned manners will increase inevitable extra cost and complexity of package manufacturing process.

### SUMMARY OF THE INVENTION

An objective of the present disclosure is to provide a side wettable semiconductor package with probe marks, wherein probe marks are easily formed on the conductive pads through a probe testing process to achieve side wettable effect.

The side wettable semiconductor package with probe mark in accordance with the present invention comprises:
a body having a bottom, a top opposite to the bottom, and four side surfaces;
multiple conductive pads formed on the bottom of the body and distributed at interval along at least two opposite edges of the bottom;
each of the multiple conductive pads comprising:
   a first surface exposed from the bottom of the body;
   a second surface abutting the first surface and exposed from one of the side surfaces of the body;
   a probe mark being hollow on the conductive pad and extending from the first surface to the second surface; and
a deforming flange formed by a pression at a periphery of the probe mark and protruding from the second surface of the conductive pad.

A method for manufacturing the side wettable semiconductor package comprises:
preparing a leadless semiconductor package, wherein the leadless semiconductor package has a body and multiple conductive pads; the body has a bottom, a top opposite to the bottom, and four side surfaces; the multiple conductive pads are formed on the bottom of the body and distributed at interval along at least two opposite edges of the bottom; each conductive pad has a first surface exposed from the bottom of the body and a second surface exposed from a side surface of the body;
conducting an electrical test to the semiconductor package, wherein each conductive pad is in contact with a lateral surface of a respective probe;
pressing each probe against the respective conductive pad to form a probe mark thereon, wherein the probe mark extends from the first surface to the second surface of the conductive pad, and a deforming flange is formed by a pression at a periphery of the probe mark.

In the electrical test step of the invention, the probe is deliberately to be in contact with and pressed on the conductive pad to form a probe mark with a proper depth. The probe mark allows the melted solder to be adhered to a side surface of the conductive pad. Accordingly, the semiconductor package has the side wettable effect for easily inspecting soldering quality of each conductive pad.

Other objectives, advantages and novel features of the invention will become more apparent from the following detailed description when taken in conjunction with the accompanying drawings.

### BRIEF DESCRIPTION OF THE DRAWINGS

FIG. 1 is a flowchart of a semiconductor package manufacturing method of the present invention;

FIG. 2 is a perspective view of a semiconductor package before electrical test;

FIGS. 3A and 3B are operational views of the semiconductor package being tested by probes;

FIG. 4 shows a perspective view of the semiconductor package having probe marks formed in the conductive pads;

FIG. 5 shows an enlarged view of the probe mark;

FIG. 6 illustrates a deforming flange formed on a second surface of the conductive pad;

FIGS. 7A and 7B are operational views of the semiconductor package being tested by probes of another type;

FIG. 8 shows a perspective view of the semiconductor package in FIGS. 7A and 7B that has probe marks formed in the conductive pads;

FIG. 9 shows an enlarged view of the probe mark in FIG. 8; and

FIG. 10 shows the semiconductor package of the invention being mounted on a circuit board.

### DETAILED DESCRIPTION OF THE INVENTION

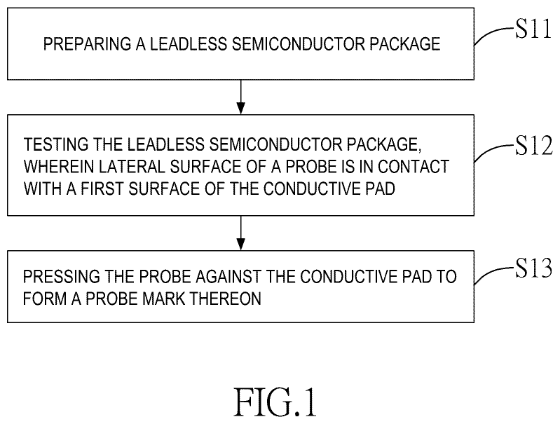

With reference to FIG. 1, the flowchart shows steps S11 to S13 for manufacturing a semiconductor package of the present invention.

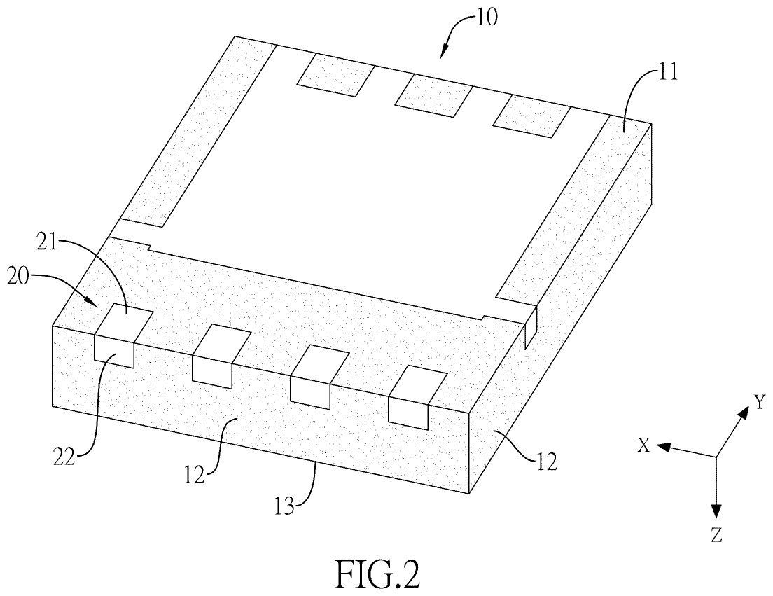

S11: Preparing a semiconductor package. With reference to FIG. 2, the semiconductor package may be a leadless semiconductor package such as a quad flat no-lead (QFN) package, a dual flat no-lead (DFN) package etc. is prepared. The semiconductor package comprise a body 10 and a plurality of conductive pads 20.

The body 10 has a bottom 11, four side surfaces 12 and a top 13. There is at least one chip (not shown) is encapsulated in the body 10. The plurality of conductive pads 20 electrically connected to the chip is formed on the body 10 and distributed alone edges of the bottom 11. According to one embodiment, the conductive pads 20 are provided at intervals along at least two opposite edges of the bottom 11. In other embodiments, the conductive pads 20 are provided at intervals along each edge of the bottom 11.

Each conductive pad 20 includes a first surface 21 and a second surface 22. The first surface 21 is exposed from the bottom 11 and substantially coplanar with the bottom 11. The second surface 22 abuts the first surface 21 and is exposed from and substantially coplanar with the side surfaces 12 of the body 10. The first surface 21 and the second surface 22 are metal-based surfaces, for example tin-plated surfaces. The leadless semiconductor package can be made by any proper packaging technology to form the body 10 and the conductive pads 20 as described above.

S12: Performing an electrical testing to the leadless semiconductor package, wherein each conductive pad 20 is in contact with a lateral surface of a respective probe 100 of a tester device. In the electrical testing process, an electrical test scheme such as a final test can be conducted to inspect whether the leadless semiconductor package has possible electrical characteristics defects.

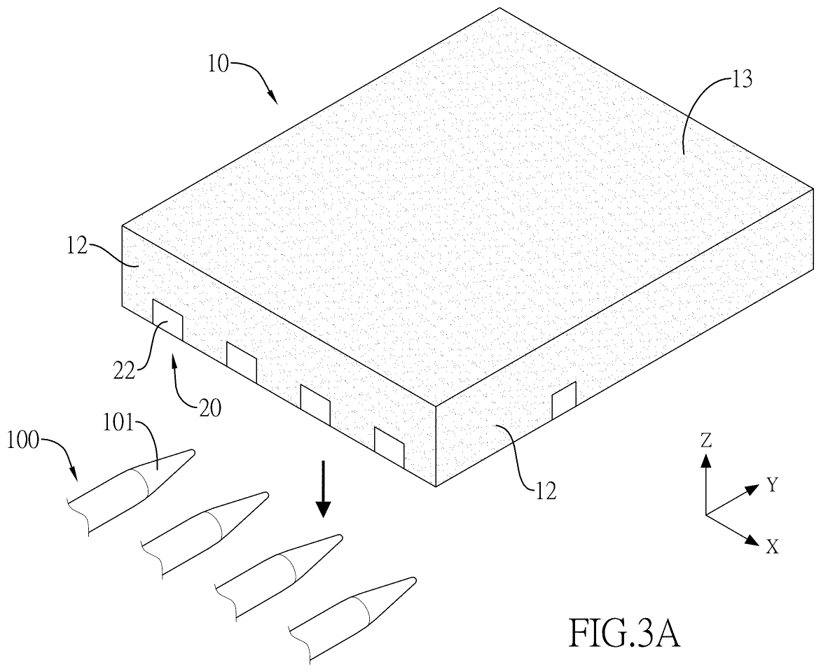

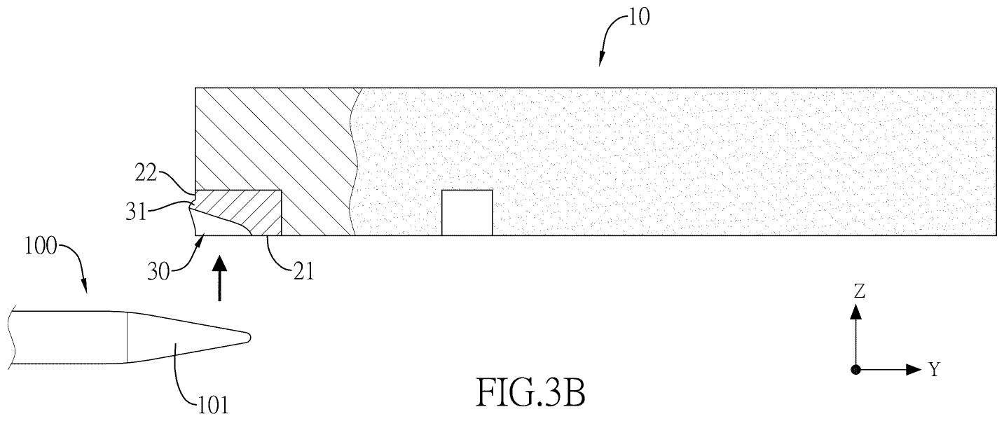

When performing a conventional electrical test, a tip of the probe 100 is placed to be directly in touch with the surface of the conductive pad for creating a single point contact between the probe and the conductive pad. However, the electrical test in accordance with the present invention is different from the point contact of the conventional test. With reference to FIGS. 3A and 3B, each of the probes 100 is purposed arranged to be laterally in contact with the first surface 21 of the respective conductive pad 20, i.e. an axis direction of the probe 100 such as the y-axis direction in FIG. 3B will be substantially parallel to the first surface 21, not perpendicular to the first surface 21. When the probe 100 laterally contacts the first surface 21 of the conductive pad 20, the tip 101 of the probe 100 is within the first surface 21 rather than exceeding the area of the first surface 21. The tip 101 is directed toward a center line of the body 10, and a lateral contacting area between the probe 100 and the first surface 21 is smaller than the area of the first surface 21. Depending on the tester device being used, the probes 100 may be mounted in a probe card or a test socket.

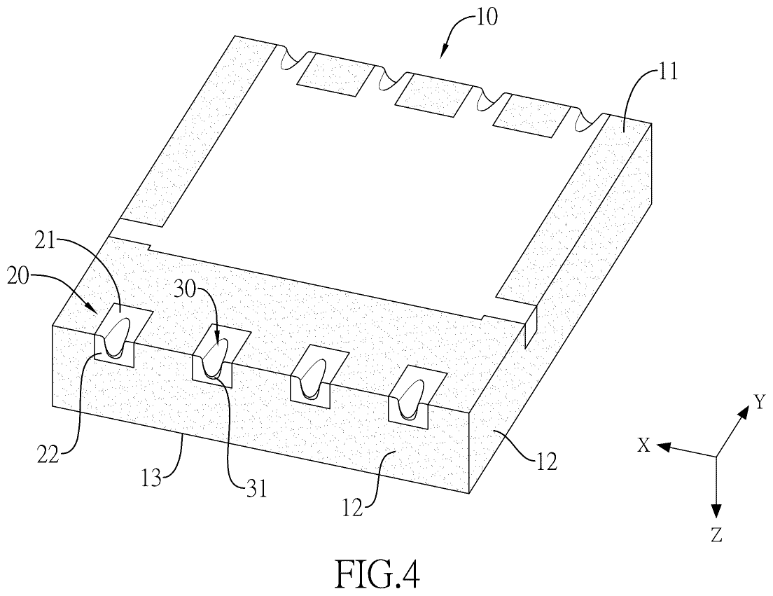

S13: Pressing each probe 100 against the respective conductive 20 to form a probe mark 30 on the probe mark 20. Referring to FIG. 4, the probe mark 30 may be an indentation extending from the first surface 21 to the second surface 22 in a sustainably oblique direction. In this embodiment, the probe mark 30 has a concaved surface with a shape corresponding to the appearance of the probe 100 in contact with. When viewing from the first surface 21, the probe mark 30 is tapered from the edge to the center of the body 10, i.e. a lateral width W of the probe mark 30 measured on the first surface 21 is gradually reduced.

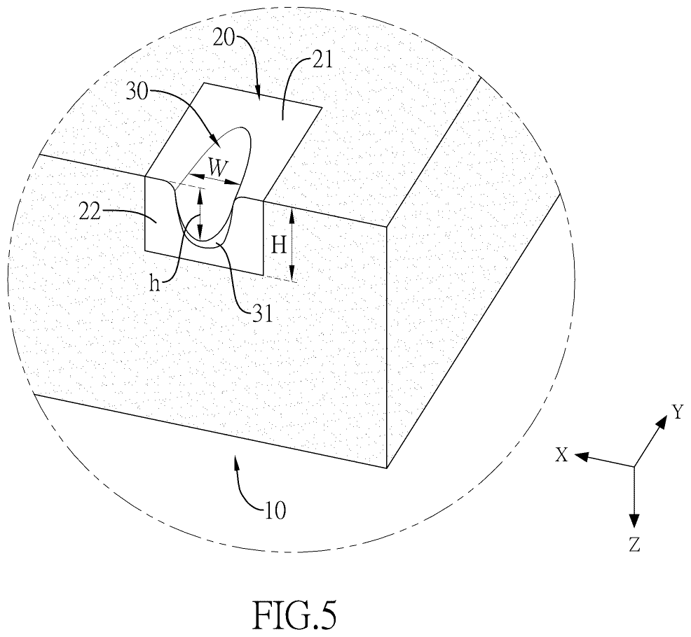

In order to form a probe mark 30 with an appropriate mark depth, the probe 100 is preferably pressed against the conductive pad 20 with a proper pressure force. For example, as shown in FIG. 5, the second surface 22 of the conductive pad 20 has a length H measured along a lengthwise direction from the bottom 11 to the top 13. Taking the length H as a reference, the probe 100 is pressed by an appropriate pressure force to the extent that a mark depth h formed on the second surface 22 will be greater than a half of the length H, i.e. h>1/2H. In another embodiment, the pressure force applied to the probe 100 may cause a mark depth h greater than 100 μm measured on the second surface 22.

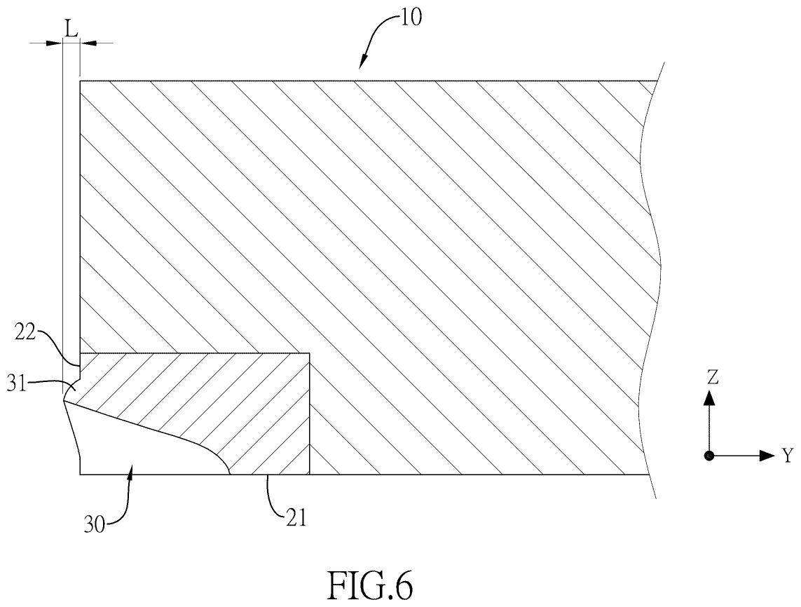

With reference to FIG. 6, a deforming flange 31 may be formed on the periphery of the probe mark 30 due to the deformation caused by probe pressing.

The deforming flange 31 protrudes from the second surface 22 of the conductive pad 20, wherein a protrusion distance L between the outermost edge of the deforming flange 31 and the second surface 22 is preferably controlled to be less than 50 μm.

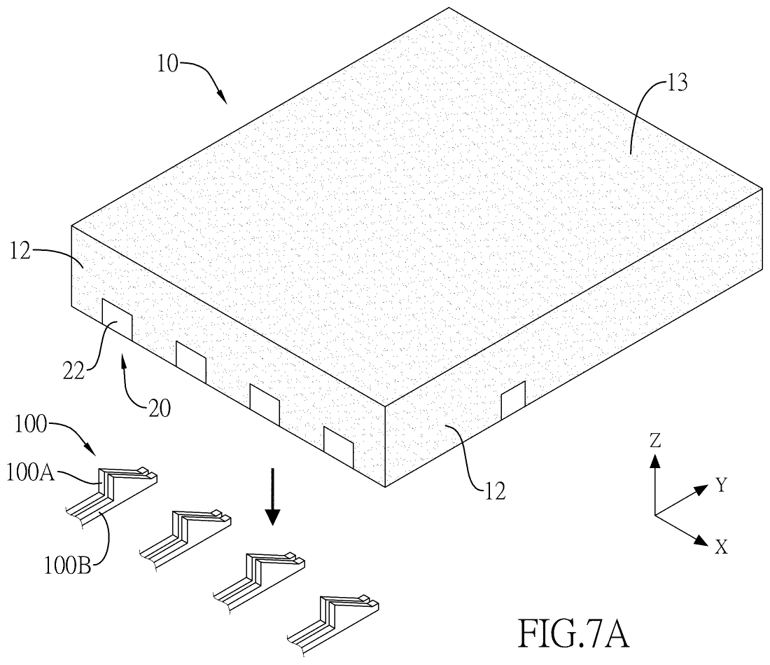

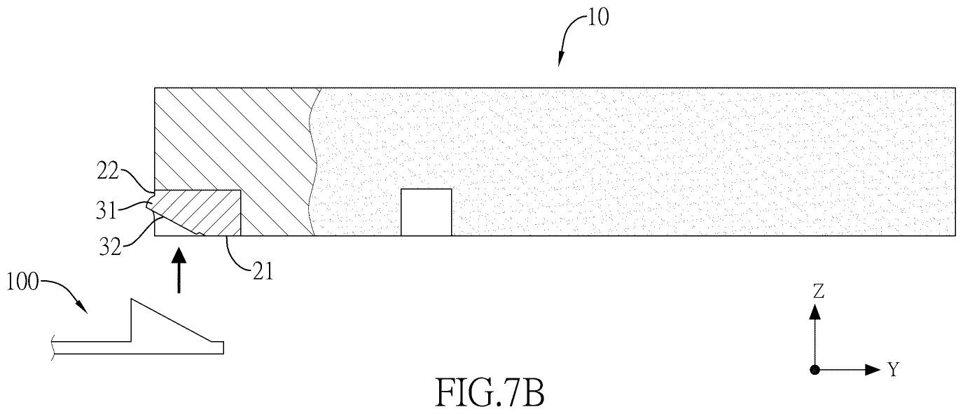

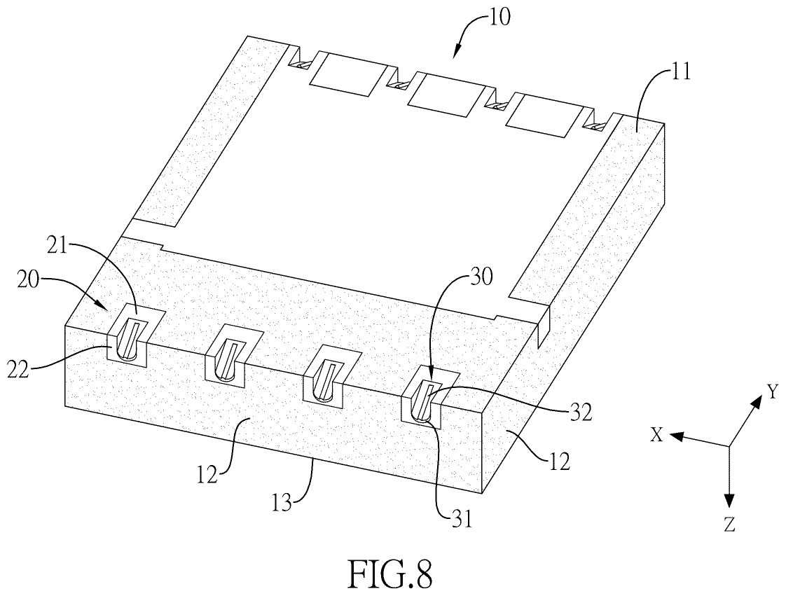

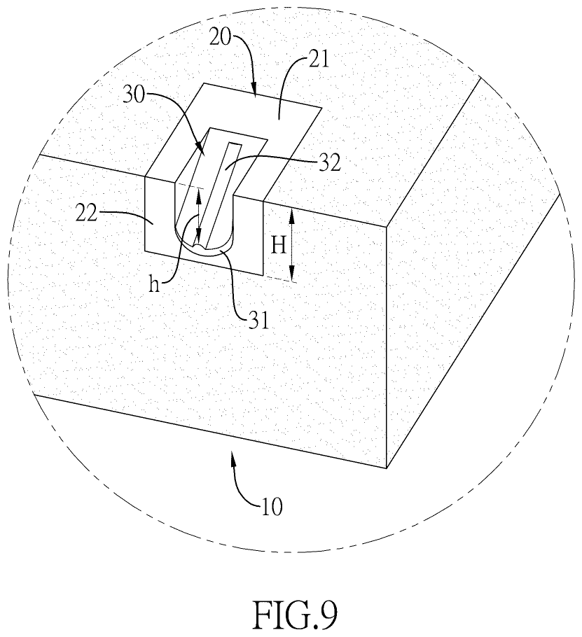

With reference to FIGS. 7A and 7B, another type of the probes 100 are applied to electrical testing process and in contact with the conductive pads 20. In this embodiment, each probe 100 for contacting a respective conductive pad 20 is composed of a pair of probe pins 100A, 100B arranged side by side, wherein each probe 100 has a substantially triangular front end. Referring to FIGS. 8 and 9, a probe mark 30 having an inclined flat surface is formed on each conductive pad 20 while the probe 100 is pressed on the conductive pad 20. A rib 32 is formed on the inclined flat surface and extends in a direction substantially parallel to the inclination direction of the inclined flat surface

The side wettable semiconductor package in accordance with the present invention comprises a body 10 as well as a plurality of conductive pads 20. The body 10 has a bottom 11, a top 13 opposite to the bottom 11, and four side surfaces 12. The plurality of conductive pads 20 are provided on the bottom 11 and along at least two opposite edges of the bottom 11. Each conductive pad 20 has a first surface 21, a second surface 22 and a probe mark 30. The first surface 21 exposed from the bottom 11 abuts the second surface 22 exposed from the side surface 12. Each probe mark 30 is an indentation on the conductive pad 20 and obliquely extends from the first surface 21 to the second surface 22, wherein a depth of the probe mark 30 measured on the second surface 22 is defined as a mark depth h. In order to ensure soldering reliability, the mark depth h measured will be greater than a half of the length H of the second surface 22. A deforming flange 31 may be formed on the periphery of the probe mark 30 due to deformation. The deforming flange 31 may protruding from the first surface 21 or the second surface 22 of the conductive pad 20.

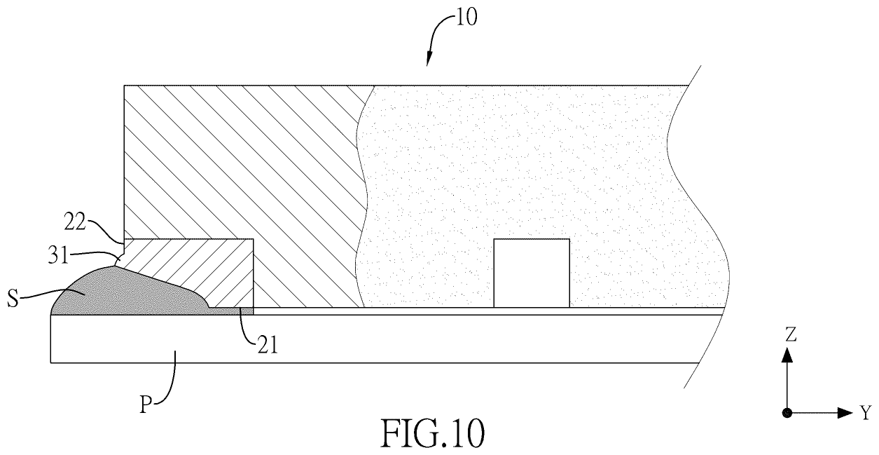

With reference to FIG. 10, since each conductive pad 20 of the body 10 has a probe mark 30 formed thereon, much solder S may wet and be contained in the probe mark 30 when the conductive pad 20 is electrically mounted on a circuit board P. The soldering status of each conductive pad 20 can be easily inspected by checking side surfaces 12 to determine whether the semiconductor package is connected to the circuit board P well.

In the electrical test in accordance with the invention, the probe is arranged to be laterally in contact with the conductive pad to form a probe mark with a proper depth. The probe mark allows the melted solder to be adhered to a side surface, i.e. the second surface, of the conductive pad. Accordingly, the semiconductor package qualifies the requirement of side wettable, by which solder quality can be inspected from the side surfaces of the semiconductor package.

In short, the present invention can easily forms the probe marks wettable by solder on the conductive pads without using specific lead frame and without performing particular manufacturing processes such as cutting and etching. Therefore, the overall cost and time of fabricating semiconductor package of the present invention may be saved.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A side wettable semiconductor package with probe marks comprising:
a body having a bottom, a top opposite to the bottom, and four side surfaces;
multiple conductive pads formed on the bottom of the body and distributed at interval along at least two opposite edges of the bottom;
each of the multiple conductive pads comprising:
a first surface exposed from the bottom of the body;
a second surface abutting the first surface and exposed from one of the side surfaces of the body;
a probe mark being hollow on the conductive pad and extending from the first surface to the second surface; and
a deforming flange formed by a pression at a periphery of the probe mark and protruding from the second surface of the conductive pad.

2. The side wettable semiconductor package as claimed in claim 1, wherein the multiple conductive pads are distributed at interval along each edge of the bottom.

3. The side wettable semiconductor package as claimed in claim 1, wherein the second surface of each conductive pad has a length measured along a lengthwise direction from the bottom to the top of the body;
the probe mark has a mark depth measured on the second surface;
the mark depth is greater than a half of the length of the second surface of the conductive pad.

4. The side wettable semiconductor package as claimed in claim 2, wherein the second surface of each conductive pad has a length measured along a lengthwise direction from the bottom to the top of the body;
the probe mark has a mark depth measured on the second surface;
the mark depth is greater than a half of the length of the second surface of the conductive pad.

5. The side wettable semiconductor package as claimed in claim 1, wherein a mark depth of the probe mark measured on the second surface is greater than 100 μm.

6. The side wettable semiconductor package as claimed in claim 2, wherein a mark depth of the probe mark measured on the second surface is greater than 100 μm.

7. The side wettable semiconductor package as claimed in claim 1, wherein a protrusion distance between an outermost edge of the deforming flange and the second surface is less than 50 μm.

8. The side wettable semiconductor package as claimed in claim 1, wherein each probe mark has a concaved surface with a width tapered from the edge of the bottom to a center of the body.

9. The side wettable semiconductor package as claimed in claim 2, wherein each probe mark has a concaved surface with a width tapered from the edge of the bottom to a center of the body.

10. The side wettable semiconductor package as claimed in claim 1, wherein each probe mark has an inclined flat surface, and a rib is formed on the inclined flat surface and extending in a direction substantially parallel to an inclination direction of the inclined flat surface.

11. The side wettable semiconductor package as claimed in claim 2, wherein each probe mark has an inclined flat surface, and a rib is formed on the inclined flat surface and extending in a direction substantially parallel to an inclination direction of the inclined flat surface.
